(19) United States
(12) Patent Application Publication
(10) Pub. No.: US 2026/0312434 A1
(43) Pub. Date: Oct. 8, 2026

(54) SYSTEM AND METHOD FOR OPTICALLY TRANSMITTING ELECTRICAL POWER OR COMMUNICATIONS SIGNALS

(71) Applicant: University of Connecticut, Farmington, CT (US)

(72) Inventors: Tobias Saule, New Haven, CT (US); Carlos A. Trallero, Storrs, CT (US); Shengli Zhou, Mansfield, CT (US); Kevin Lindstrom, Vernon, CT (US)

(21) Appl. No.: 19/642,269

(22) Filed: Apr. 8, 2026

Related U.S. Application Data
(60) Provisional application No. 63/785,415, filed on Apr. 8, 2025.

(51) Int. Cl. H02J 50/30; G02F 1/01; H04B 10/11; H04B 10/80; H10F 55/20

(52) U.S. Cl. CPC H02J 50/30; H04B 10/11; H04B 10/807; G02F 1/0136; H10F 55/20

(57) ABSTRACT

An optical transfer system and method of operation are disclosed. The optical transfer system includes a transmitter and at least one receiver. The transmitter has an optical source in communication with a gain-medium free optical cavity, the transmitter configured to emit a beam of coherent light. The at least one receiver is positioned to receive the beam of coherent light and generate a signal in response.

### CROSS-REFERENCE TO RELATED APPLICATIONS

The present Application is a nonprovisional application and claims the benefit of U.S. Provisional Application Ser. No. 63/785,415 entitled “Gain-Medium Free Remote Charging Via Free Space Enhancement Cavity Over Multiple Meters” filed on Apr. 8, 2025, the contents of which is incorporated herein by reference.

### STATEMENT REGARDING FEDERALLY SPONSORED RESEARCH

This invention was made with government support under grant number 2332172 awarded by the National Science Foundation. The government has certain rights in the invention.

### BACKGROUND

### 1. Field of the Invention

Embodiments of the invention disclosed herein relate to optical power transmission, and in particular to use of gain-free media or gain-medium free configurations in optical cavities.

### 2. Description of the Related Art

Free-space optical power transfer and related “remote charging” or “wireless power transfer” techniques have been investigated for delivering electrical energy to spatially separated electronic devices using an optical beam transmitted through an air path and converted at a receiver by an optical-to-electrical converter such as a photovoltaic element. Such systems may be deployed in indoor environments (e.g., consumer electronics charging) and in other environments where wired power delivery is impractical or undesirable. Optical power transfer may be combined with optical communication over a shared link, which may use modulation of one or more optical fields and corresponding photodetection to convey information between a transmitter and a receiver.

Existing free-space optical power transfer systems that rely on a direct propagating beam may present safety and deployment limitations. For example, an optical beam that is sufficiently powerful to deliver usable electrical power to a remote receiver may exceed exposure limits under some conditions, particularly where a line-of-sight path can be intercepted by an unintended object. Distributed Laser Charging (DLC) is one gain-medium based cavity technology that alleviates that issue. Separately, practical installations may be affected by pointing error, building motion, air turbulence, particulate contamination, and receiver motion, each of which can reduce coupling efficiency at the receiver and can increase the complexity of alignment and tracking subsystems. Multi-receiver scenarios may further complicate alignment and power allocation because separate receivers may occupy different spatial locations and may move independently, and because power transfer may be constrained by per-beam exposure limits and by cross-talk among spatial channels.

Accordingly, while existing free-space optical power transfer systems may be suitable for their intended purpose the need for improvement remains, particularly in providing a free-space optical power transfer and/or communication architecture having features described herein.

### SUMMARY

In accordance with one aspect of the disclosure an optical transfer system is provided. The optical transfer system includes a transmitter and at least one receiver. The transmitter has an optical source in communication with a gain-medium free optical cavity, the transmitter configured to emit a beam of coherent light. The at least one receiver is positioned to receive the beam of coherent light and generate a signal in response.

In accordance with another aspect of the disclosure an optical transfer system is provided. The optical transfer system includes a transmitter, at least one receiver, and a controller. The transmitter has an optical source in communication with a gain-medium free optical cavity, the transmitter configured to emit a beam of coherent light. The at least one receiver is positioned to receive the beam of coherent light and generate a signal in response. The at least one controller is operably coupled to the transmitter and at least one receiver, the controller having a processor operable to execute computer instructions to perform a method comprising: causing the transmitter to emit the beam of coherent light towards the receiver; causing the receiver to receive the beam of coherent light and generate a signal in response to receiving the beam of coherent light; and storing the signal in at least one of a controller memory or an energy storage device.

According to still another aspect of the disclosure, a wireless electrical power and communication transfer system is provided. The wireless electrical power and communication transfer system includes a transmitter and at least one receiver. The transmitter includes: an optical light source; at least one of an active optical device or an adaptive optical device configured to emit a light beam received from the light source; and at least one lens configured to collimate the light beam. The at least one receiver is positioned to receive the light beam, the at least one receiver comprising: a beamsplitter configured to reflect at least a first portion of the received light beam and allow a second portion of the received light beam to pass through; a photovoltaic cell positioned to receive the first portion; and a mirror positioned to receive the second portion.

These and other advantages and features will become more apparent from the following description taken in conjunction with the drawings.

### BRIEF DESCRIPTION OF THE DRAWINGS

The subject matter, which is regarded as the disclosure, is particularly pointed out and distinctly claimed in the claims at the conclusion of the specification. The foregoing and other features, and advantages of the disclosure are apparent from the following detailed description taken in conjunction with the accompanying drawings in which:

FIG. 1A illustrates a laser based data and power transfer system according to an embodiment;

FIG. 1B illustrates an laser based data and power transfer system within the interior of a building according to an embodiment;

FIG. 2A, FIG. 2B, and FIG. 2C are schematic illustrations of a resonant cavity according to an embodiment;

FIG. 3 is a schematic illustration of a resonant beam-based charging and communication system according to an embodiment;

FIG. 4 is a schematic illustration of a ring bow-tie resonator according to an embodiment;

FIG. 5 is a chart illustrating cavity resonances as piezo length changes according to an embodiment;

FIG. 6 is a schematic illustration of a ring resonator according to another embodiment;

FIG. 7 is a schematic illustration of a system using two lenses and two curved mirrors according to an embodiment; and

FIG. 8 is a schematic illustration of a system using a seeded cat-eye optical cavity according to an embodiment.

The detailed description explains embodiments of the disclosure, together with advantages and features, by way of example with reference to the drawings.

### DETAILED DESCRIPTION

Disclosed herein are techniques for free-space optical power transfer, data transfer, and combined power-and-data transfer. An extended optical resonator spanning a transmitter/access-point side and a receiver/client-device side may support efficient power delivery and/or optical communications while reducing exposure when a line-of-sight path is interrupted. A system employing the techniques disclosed may support high throughput under an impedance-matched enhancement-cavity condition using a passive cavity injected or seeded by an external optical source without a gain medium, with resonator control that may maintain operation at or near resonance using loose-lock techniques.

Further disclosed herein are embodiments that include a seeded, gain-medium-free optical cavity to perform charging, establish a communications link, or a combination thereof.

The technology disclosed may be useful in environments that rely on distributed electronic devices and localized power delivery. One example is a manufacturing facility in which sensors, controllers, and inspection systems are positioned throughout a production line. Another example in a manufacturing facility includes fabrication equipment, such as three-dimensional printing head or additive manufacturing systems.

The ability to deliver electrical power without wired connections reduces installation complexity and permits reconfiguration of equipment without modification of existing infrastructure. Further applications include, but are not limited to, Internet-of-Things (IoT) devices, remote sensing, augmented-reality (AR)/virtual-reality (VR) training simulators, gantry systems where cable bundles impact balance and/or precision, drone networks, and smart badges/cards, for example.

For example, the technology disclosed may be useful in logistics and warehousing environments that employ automated systems. Equipment such as scanners, tracking devices, and mobile platforms may be powered without reliance on battery replacement or wired charging stations. The reduction in manual intervention supports continuous operation and reduces downtime associated with charging cycles.

The technology disclosed may be useful in environments that provide monitoring over extended areas. Examples include agricultural installations, environmental monitoring systems, power plants, and infrastructure inspection systems. Devices positioned across a field or along a structure may receive electrical power signals or communication signals without installation of dedicated wiring to each location.

The technology disclosed may be useful in environments that include mobile or repositionable equipment. Examples include aerial vehicles, robotic platforms, and movable instrumentation. Delivery of electrical power without physical connection allows operation over a range of positions without interruption for charging.

The technology disclosed may be useful in consumer environments in which multiple devices are present within a confined space. Devices such as communication devices, entertainment systems, and control units may receive electrical power without reliance on individual charging cables. Reduction of cabling reduces obstruction and simplifies the arrangement of devices within the space.

The system provides a reduction in optical exposure when a line-of-sight path is interrupted. Interruption of the optical path disrupts resonance within the optical resonator and reduces circulating optical power. The reduction in circulating optical power limits the optical energy delivered along the interrupted path.

The system provides efficient transfer of optical power under an impedance-matched condition of the optical resonator. Selection of reflectivity and transmission of optical elements limits internal losses and supports delivery of optical power to an optical-to-electrical converter.

The system provides tolerance to variation in alignment and position of a receiver. Optical elements maintain resonator stability over a range of distances and alignment conditions. This configuration permits operation without precise pointing of a beam to a fixed location.

The system provides scalability to multiple devices through support of multiple optical modes. Distribution of optical power among multiple devices is achieved without establishing separate transmission paths.

The system provides capacity for communication through modulation of an optical field within the optical resonator. The modulation is performed without interrupting delivery of electrical power.

Delivered electrical power may be generated at a remote optical-to-electrical converter from a controlled out-coupled portion of circulating power, while additional cavity losses are limited by selection of coupler transmissions and mirror reflectivities. In an embodiment, the losses of the input couple equal the roundtrip losses in the cavity. For charging/power-transfer applications, another condition is that the cavity losses are dominated by the losses/transmission of the output coupler. In this way the power is transferred or “leaves” the cavity through the output coupler and goes toward the receiver/client. Scalability may be provided by supporting multiple resonator eigenmodes to distribute power among multiple beams and/or receivers while maintaining per-beam constraints. Working distance and alignment tolerance may be improved using resonator-stability optics, including lens-curved mirror combinations and cat-eye retroreflector end optics. intra-cavity and extra-cavity adaptive elements, such as a spatial light modulator, deformable mirror, and/or acousto-optic modulator, may multiplex spatial channels, compensate for misalignment, aberration, or scattering based on feedback sensing, and encode downstream and upstream communication while maintaining resonator operation.

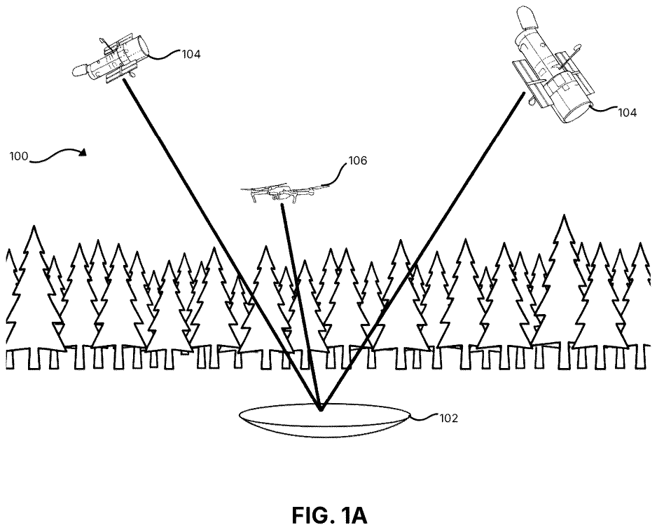

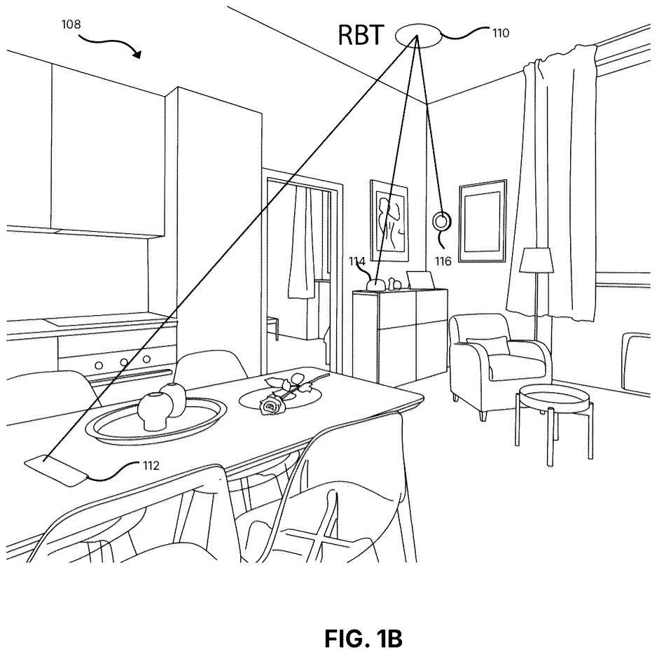

Further disclosed herein is a ,multi-mode, extended-cavity laser system capable of wireless communication and remote charging over long distances. The system provides much of the functionality of near-field wireless systems, where client devices can communicate and charge over the same electromagnetic signal, but also extends the usable distance of combined wireless ,power transfer, and communication—through the use of the gain-medium-free optical cavity. Potential applications of such a system include ground-to-space communication and implementation into sixth-generation network protocols, such as those shown in FIG. 1A and FIG. 1B.

As used herein, the term “active optical device generally refers to an optical device configured to modify a wavefront of an optical field in response to a control signal. An active optical device maintains the shape of mirrors by correcting for slow, structural distortions caused by gravity, temperature changes, and mechanical stress. Active optical devices may use actuators behind the mirror to adjust the mirrors shape in real-time. In general, an active optical device operates at a lower frequency than an adaptive optics device. In some embodiments, the active optical devices may further include devices that provide intensity modulation as well.

As used herein, the term “adaptive optics element” generally refers to an optical device configured to modify a wavefront of an optical field in response to a control signal. An example of an adaptive optics element includes a spatial light modulator configured to apply a phase mask to compensate for aberration or to control propagation of an optical field. Similar examples include deformable mirrors and other controllable optical surfaces. Generally, these examples provide response time sufficient to support control of the optical field and resolution sufficient to modify spatial characteristics of the optical field. In one or more embodiments, the adaptive optics element may be a deformable mirror, such as a Model DMP40-F01 piezoelectric deformable mirror manufactured by Thorlabs, Inc. of Newton, NJ or a Model ILAO STAR deformable mirror manufactured by Imagine Optic, Inc. of Orsay, France.

As used herein, the term “spatial light modulator” generally refers to an optical device configured to impose a spatially varying phase and/or amplitude profile on an incident optical field. An example of a spatial light modulator includes a reflective liquid-crystal-on-silicon device having a pixelated array in which each pixel is configured to impart a controllable phase shift to incident light, such that a phase mask defines propagation of the optical field within an optical cavity. Similar examples include transmissive liquid-crystal devices, microelectromechanical mirror arrays, deformable mirrors, and digital micromirror devices. Generally, these examples provide operation at a wavelength compatible with the optical cavity, phase resolution sufficient to control optical modes, and a refresh rate sufficient to support control or modulation of the optical field. In one or more embodiments, the spatial light modulator may include a Model PLUTO-2.1 manufactured by Holoeye Photonics AG of Berlin, Germany.

As used herein, the term “optical source” generally refers to a device configured to generate electromagnetic radiation for injection into an optical cavity. An example of an optical source includes a laser configured to emit radiation at a wavelength selected for compatibility with optical elements and an optical-to-electrical converter. Similar examples include diode lasers, fiber lasers, solid-state lasers, and externally injected optical fields used to seed a passive optical cavity. Generally, these examples include spectral compatibility with reflective and transmissive optical elements, stability sufficient to support resonant operation of the optical cavity, and wavelengths that support conversion at an optical-to-electrical converter.

As used herein, the term “optical cavity” generally refers to an arrangement of optical elements configured to support resonant circulation of an optical field along a defined path. An example of an optical cavity includes a resonator defined by reflective elements and at least one coupling element configured to inject an optical field and to extract a portion of circulating optical power. Similar examples include linear resonators, ring resonators, bow-tie resonators, and cat-eye retroreflector arrangements. Generally, these examples provide control of internal losses relative to coupling elements, maintenance of alignment within stability conditions, and operation at or near resonance under a control scheme.

As used herein, the term “enhancement cavity” generally refers to an optical cavity configured such that circulating optical power within the cavity exceeds input optical power under a resonant condition. An example of an enhancement cavity includes a cavity configured to satisfy an impedance-matched condition in which reflectivity of an input coupling element corresponds to total effective reflectivity of the cavity, such that input optical power is efficiently coupled into circulating power. Similar examples include cavities configured with selected reflectivity and transmission values to control internal loss and output coupling. Generally, these examples provide maintenance of resonance conditions, control of cavity losses, and compatibility of optical elements with circulating optical power.

As used herein, the term “optical-to-electrical converter” generally refers to a device configured to convert incident optical radiation into electrical energy. An example of an optical-to-electrical converter includes a photovoltaic element positioned to receive a portion of circulating optical power extracted from an optical cavity. Similar examples include photodiodes and semiconductor conversion devices configured to generate electrical current in response to incident optical radiation. Generally, these examples provide spectral compatibility with the optical source, thermal handling of incident power, and electrical characteristics suitable for delivery to a load or storage element.

As used herein, the term “beam splitter” generally refers to an optical element configured to divide an incident optical field into multiple portions. An example of a beam splitter includes a partially reflective optical element configured to reflect a first portion of an optical field toward an optical-to-electrical converter and to transmit a second portion within an optical cavity. Similar examples include plate beam splitters, cube beam splitters, and other partially reflective optical components. Generally, these examples provide reflectivity and transmission to control distribution of optical power and compatibility with the wavelength of the optical field. In one or more embodiments, the beam splitter may include a Model PBS052 manufactured by Thorlabs, Inc. of Newton, NJ.

As used herein, the term “adaptive optics element” generally refers to an optical device configured to modify a wavefront of an optical field in response to a control signal. An example of an adaptive optics element includes a spatial light modulator configured to apply a phase mask to compensate for aberration or to control propagation of an optical field. Similar examples include deformable mirrors and other controllable optical surfaces. Generally, these examples provide response time sufficient to support control of the optical field and resolution sufficient to modify spatial characteristics of the optical field. In one or more embodiments, the adaptive optics element may include a SLM such as Model PLUTO-2.1 manufactured by Holoeye Photonics AG of Berlin, Germany.

As used herein, the term “parametric conversion crystal” generally refers to a non-centrosymmetric optical crystal (often beta-barium borate, BBO, or lithium triborate, LBO) used to convert high-energy photons into pairs of lower-energy photons through nonlinear optical processes, most commonly spontaneous parametric down-conversion (SPDC). Parametric conversion crystals may be used for frequency conversion. In one or more embodiments, the parametric conversion crystal may include crystals produced by United Crystals, Inc. of Port Washington, NY or MolTech GmbH of Berlin, Germany.

As used herein, the term “cat-eye retroreflector” generally refers to an optical arrangement configured to return an incident optical field toward a source over a range of incident angles. An example of a cat-eye retroreflector includes a lens and a reflective element arranged such that light entering the lens is focused onto the reflective element and returned along a path toward the source. Similar examples include corner-cube reflectors and other retroreflective arrangements. Generally, these examples provide maintenance of alignment within a field of view and compatibility with an optical cavity configuration.

As used herein, the term “loose-lock” generally refers to a control condition in which an optical cavity is maintained near a resonant condition without continuous high-precision locking. An example of loose-lock includes operation in which control of cavity length or optical phase maintains circulating optical power within a range sufficient for power transfer while tolerating variation in alignment or environmental conditions. Similar examples include control schemes that periodically adjust cavity parameters to maintain resonance. Generally, these examples include sufficient stability to sustain circulating optical power and tolerance to variations in cavity parameters.

As used herein, the term “impedance-matched condition” generally refers to a relationship between an input coupling element and an optical cavity in which input optical power is efficiently coupled into circulating optical power. An example of an impedance-matched condition includes selection of reflectivity of an input coupling element to correspond to total effective reflectivity of the optical cavity. Similar examples include configurations in which transmission and reflection parameters are selected to minimize reflection of input power. Limitations for these examples include maintenance of cavity parameters and control of internal losses to sustain the condition.

As used herein, the term “energy storage device” generally refers to a device configured to receive electrical energy generated by an optical-to-electrical converter and to store the electrical energy for subsequent use by a load. An example of an energy storage device includes a rechargeable battery configured to store electrical energy and to provide electrical output to a device. Similar examples include lithium-ion batteries, lithium polymer batteries, nickel-metal hydride batteries, lead-acid batteries, solid-state batteries, capacitors, supercapacitors, ultracapacitors, and hybrid storage devices combining battery and capacitive elements. Generally, these examples provide storage of electrical energy at a capacity and discharge rate suitable for operation of an associated device, compatibility with an electrical output of the optical-to-electrical converter, and integration with power management circuitry to regulate delivery of electrical energy to the load.

The term “Sixth-generation network protocols (6G)” generally refers to candidate specifications, procedures, and air-interface techniques contemplated for implementation in a sixth-generation wireless communication system, including protocols supporting operation over heterogeneous spectrum bands and heterogeneous infrastructure. Such protocols may define signaling formats, timing structures, duplexing arrangements, network registration and mobility procedures, quality-of-service and scheduling mechanisms, and security procedures for exchanging user-plane data and control-plane data between user equipment and one or more network nodes.

It should be appreciated by those skilled in the art that while embodiments herein may describe or illustrate a particular optical cavity, this is for example purposes and the claims should not be so limited. It should be appreciated by those of skill in the art that any gain-medium free optical cavity may be used without deviating from the teachings provided herein. The gain-medium free optical cavity may include cat-eye retroreflecting configurations or bowtie cavity configurations for example.

In the embodiment of FIG. 1A, the system 100 includes active optics or adaptive optic elements such as a spatial light modulator 102 (SLM) or a deformable mirror that is configured as described herein. The active or adaptive optic element provides laser communication and electrical charging capabilities with a variety of devices in the environment, such as but not limited to satellites 104 and aerial vehicles 106. Each of the satellites 104 and the aerial vehicles 106 contains an energy storage system (not shown). The energy storage system receives power from the SLM 102 and stores the power for use by the respective device (i.e., satellite 104 or aerial vehicle 106). It should be appreciated that while embodiments herein illustrate and describe transmissive adaptive optics, but the claims should not be so limited, in other embodiments the system may utilize transmissive optics, reflective adaptive optics, or a combination thereof. In embodiments, an adaptive optic in either configuration may achieve the same result, but one is reflective and the other is transmissive.

It should be appreciated that embodiments described herein are not limited to exterior applications such as those shown in FIG. 1A. In the embodiment of FIG. 1B, the system 108 includes a spatial light modulator 102 that is mounted or positioned within the interior of a building, such a house for example. The spatial light modulator 110 provides communication and electrical charging capabilities with devices within the building, such as but not limited to a cell phone 112, entertainment device 114, and thermostat 116. It should be appreciated that the spatial light modulator 110 may be coupled to communicate and transfer data between the devices and a local area network, a wide area network, or the Internet for example.

Through the use of an active or adaptive optic element, embodiments herein seek to extend the usable distance between the transmitter and receiver by compensating for cavity losses and scattering. Additionally, the active or adaptive optic element can be used to extend the region of allowed receiver translations by using sloped phase masks, which can be loaded into the local memory of the device.

Embodiments disclosed herein provide for the configuration and optimizing if a long range optical resonant cavity for a single charging station and client. In other embodiments, the system is scalable to multiple users. The system may further be tuned for transmission at different distances. The system provides for multiple clients where channel-to-channel interference with adaptive optics (AO) is mitigated. Information transfer for a multiple client system may use aspects of the AO to implement parallel upstream and downstream communication. Echo interference for implementations without an adaptive optic is mitigated. As described herein, “echo interference” refers to the degradation of the communication signal from the unwanted interference caused by the reflections in the cavity. In some embodiments, harmonic generation and optical bandpass filters may be used to deal with this unwanted effect.

### Single Channel Verification

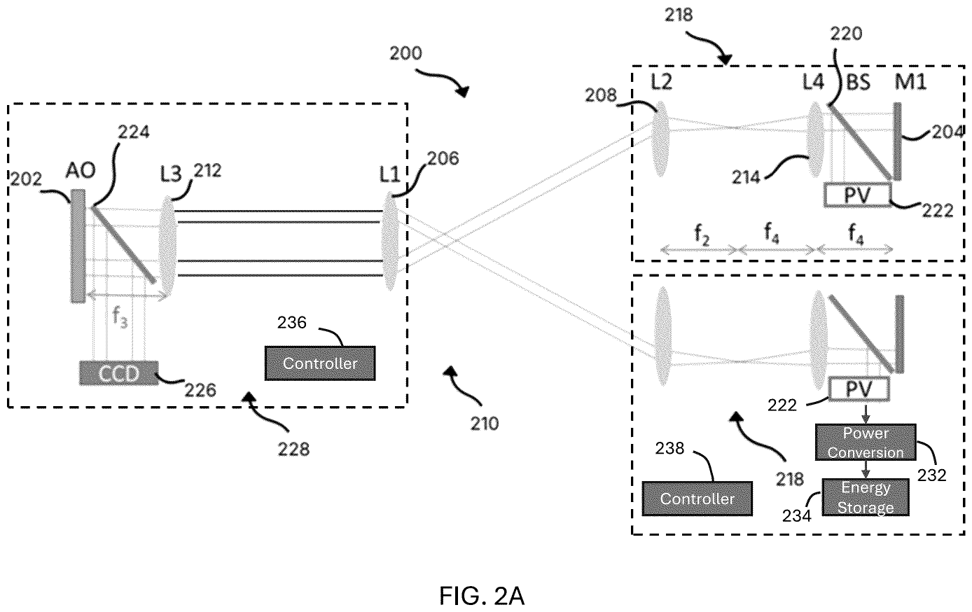

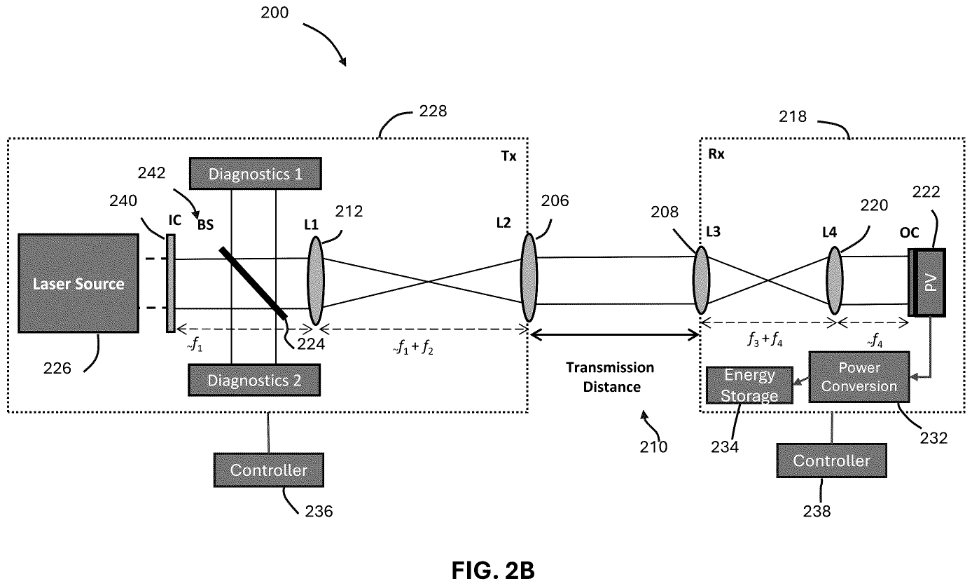

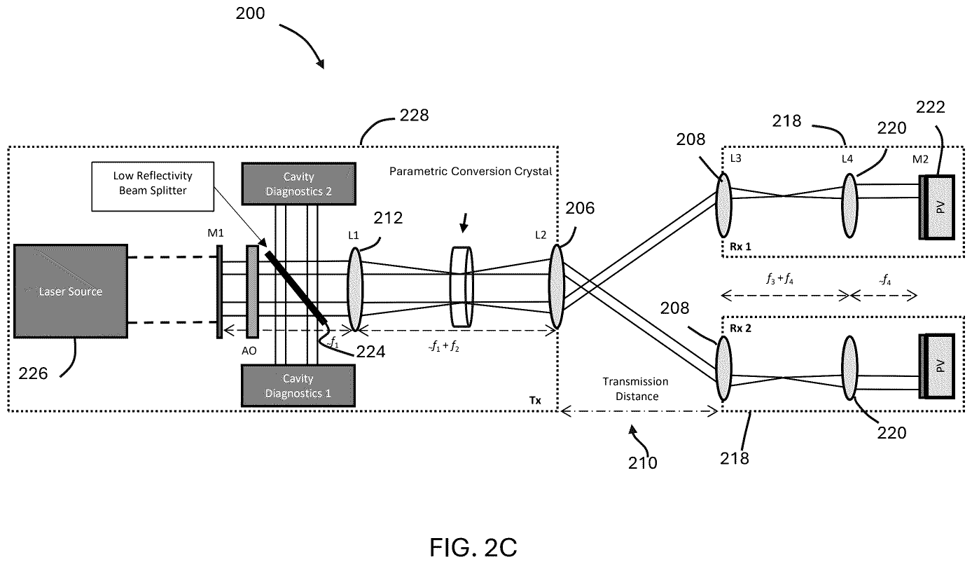

Referring now to FIG. 2A, an embodiment is shown for evaluating and optimizing a resonant cavity. In an embodiment, the light source for system 200 is a gain-medium-free having an optical cavity that is injected with a seed laser, and the light is transmitted through the first mirror, the input coupler, and forms the resonant mode. In this example, the ends of the cavity are defined by M1 and the adaptive optics element 202 AO. In this embodiment, system 200 includes a transmitter 228 and at least one receiver 218. The system 200 includes collimating lens 206 L1 and collimating lens 208 L2 collect and collimate the light traveling in free space 210 while relay lens 212 L3 and relay lens 214 L4 are simply relay optical elements. On the receiver 218 end, there is a beam splitter 220 used to control the ratio between the light kept in the cavity and the power used towards the photovoltaic element 222 (PV). This starts with a plane mirror 204 in place of the AO as performance and needs of the system are characterized.

In an embodiment the electrical power generated by the photovoltaic element 222 is transferred via an optional power electronics/converter 232 which adapts and transfers the electrical power to an energy storage device 234. The transmitter 228 and receiver 218 may each include a controller 236, 238. The controller 236, 238 is responsive to executable computer instructions for causing the respective transmitter 228 and receiver 218 to operate in the manner described herein.

In an embodiment, the output light of the transmitter 228 is “eye-safe.” In some embodiments, an eye-safe laser light is one that complies with ANSI standard Z136. In one or more embodiments, the laser light is a visible is configured such that the blink reflex of a person limits the exposure to no more than 0.25 seconds. It is contemplated that Class 1, Class 2, or Class 3 laser light may be used.

It should be appreciated that the system 200 may be scaled to a variety of power levels depending on the application. In applications for sensors or IoT devices for example, a transfer power may be on the order of fractions of a milliwatt to less than a Watt. In applications involving slow charging of an energy storage device or maintaining a cellular phone charge, a low power of 1-2 Watts may be used. These lower power levels may provide technical advantages to prioritize safety and efficiency, such as for long-range or small laser systems. In still further embodiments, higher power systems, such as 5-10 Watts or up to 100 Watts which may be suitable for faster charging rates. If should be appreciated that systems involving higher power transfer levels may include additional heat management systems.

The efficiency of converting laser light into electrical energy using a photovoltaic cell (typically ~30-40%) determines how much of the laser's power is usable for charging. A 0.7 Watt of optical power output with a 40% conversion efficiency would result in 0.26 Watts of electrical power. For 5 W laser may provide 1.5-2 W of actual charging power after conversion losses. In some embodiments, technical advantages are achieved in improving the efficiency of the photovoltaic element due to the input light having a relatively narrow band of wavelengths.

The embodiment of FIG. 2B illustrates a system 200 that is similar to that of FIG. 2A. In this embodiment, the seed laser light source 226 transmits the seed laser light via a photonic integrated circuit 240 into the optical cavity 242.

### Scaling to Multiple Users

In some embodiments, such as system 200 of FIG. 2A, the system includes an adaptive optic element 202 (AO). In these embodiments, the purpose of the AO is two-fold: in addition to compensating for optical aberrations, the AO allows for efficient channel multiplexing. In some embodiments, an optics element 202 that is an SLM with a highly reflective dielectric backplane is used as the AO. The use of an SLM provides technical advantages compared to other adaptive optic elements because of its unique capacity to write arbitrary phase masks that modulate the wavefront. This means that phase masks that do multiple functions at the same time can be written through the use of superimposed phase masks that represent multiple optical elements. Additionally, it is possible to randomly choose pixels on the SLM and sort them into categories that each represent distinct phased optical components.

Generally, this embodiment has several technical advantages compared to the prior art. For example, the disclosed embodiment is easily scalable to multiple receivers 218 because of the multi-mode cavity. Second, an optics element 202 that is an SLM allows for compensation which may be useful to alleviate pointing drifts and tilted wavefronts. Additionally, the system 200 shown in FIG. 2A may be modified to incorporate long range information transfer.

Referring to FIG. 2C, an embodiment of the system 200 is shown. The embodiment of FIG. 2C is similar to FIG. 2A, with the addition of a parametric conversion crystal 250 disposed between the lenses 206, 212. The use of a parametric conversion crystal provides an additional wavelength in the cavity to send information over and/or to use for sensing. The use of a parametric conversion crystal may be desirable to increase data transfer rates or to provide an entirely clean communication carrier that is not resonant.

### Long Range Information Transfer

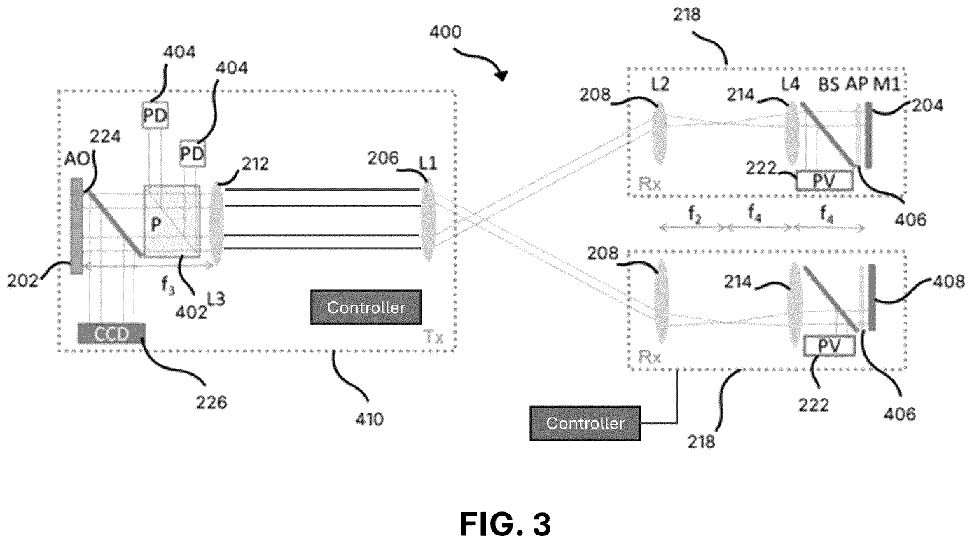

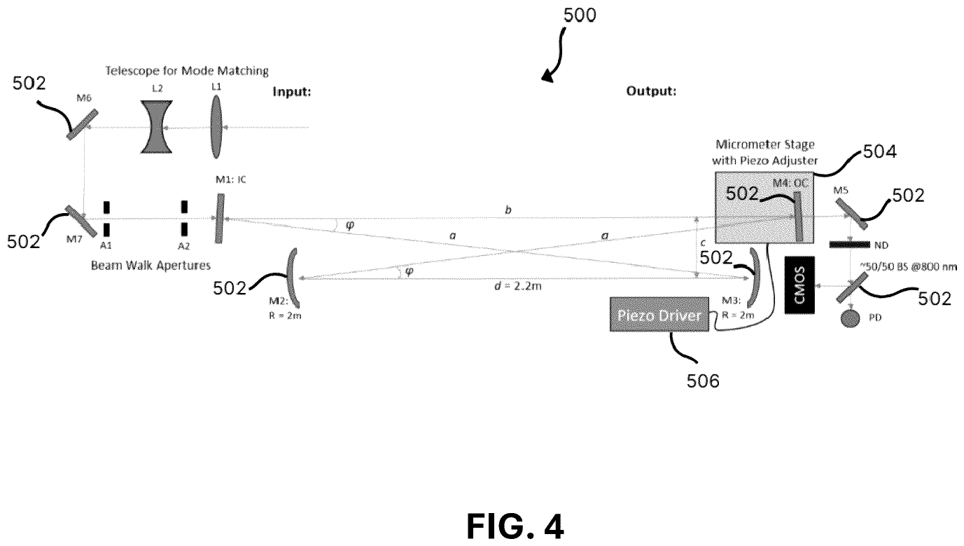

Shown in FIG. 3 are aspects of a resonant cavity that enable information transfer. In addition to the optical elements presented in the remote charging embodiment of system 200, shown in FIG. 2A, the system 400 in FIG. 3 introduces a polarizer 402 P, photodiodes 404 PD, and active waveplate 406 AP. The active waveplate 406 may also be referred to as a “retarder” or “active polarizer (AP)”. In FIG. 4, the transmitter 410 side of the system 400 and two receivers 218 are shown in boxes with in dotted perimeters. Communication signals may be transmitted through either intensity modulation, phase modulation, frequency modulation, or a combination thereof.

An example of an embodiment for a resonant beam based charging and communication system 400 is shown in FIG. 3. In this example, a few elements are added to the embodiment, such as an active waveplate 406 or retarder AP in the receiver 218 and passive polarizer 402 and photodiodes 404 in the transmitter 410. In this embodiment, data/information can be transmitted both upstream (from the receiver 218 to the transmitter 410) and downstream (from the transmitter 410 to the receiver 218), which multiple other approaches do not provide. For upstream, an active waveplate 406 that will rotate the polarization of the light in the cavity by a very small amount is used, causing the polarization of the upstream traveling light to be slightly rotated. Once that light reaches the polarizer 402 in the transmitter 410, the perpendicular polarized component of the light gets dumped onto the photodiodes 404 while light with the “correct” or desired polarization continues to travel through the cavity. It is expected to use changes in polarization of less than 1° which will change the cavity power by less than 3%. For downstream communication, active optic device or an adaptive optic device, such as the SLM 202 for example, can be used. Relay lens 212 (L3) may be configured in such a way that each mode in the SLM could have a pixel matrix of 10×10 for a total of 100 pixels. The total amount of power reflected back into the cavity can be simply controlled by adding a small wavefront tilt such that the beam is not perfectly aligned, causing the cavity to be in a “low” power state. To achieve the same effect, a fraction of the 100 pixels per mode, such as 10 for example, to create a sub-mask with a tilt such that less than 10% of the power is not reflected back into the cavity may be chosen.

If a typical commercially available SLM 202 with a 512×512 pixels is used, this can create a theoretical limit of 2600 independent receivers. Additionally, using the SLM 202 to provide downstream communication means that the refresh rate of the SLM will limit the channel capacity. At present, “fast” SLMs have refresh rates of tens of kHz, but their refresh rates will continue to improve over time, partly because SLM technology is similar to LCD monitor technology. The data rate to the receivers 218 for this embodiment will be low, on the order of the refresh rate of the SLM. However, further work and design modifications can be performed to provide high throughput communication. Additionally, a low data rate resonant beam system still has substantial market value as much of the IoT (internet of things) devices and sensors being deployed do not involve the transmission of large amounts of data, but substantially benefit from the freedom of movement and larger transmission distances provided by this approach. Advantageously, the approach yields two-way communication whereas other techniques that analytically support high channel capacity resonant beam systems have yet to account for the desired two-way communication.

Referring now to FIG. 4 a ring bow-tie resonator 500 is shown that when scaled that yields the 30th harmonic of the freq=1.01 MHz input. All mirrors 502 are highly reflective, and the reflectance of each mirror 502 was tuned to a desired power. In this embodiment, the total cavity length is 9.8912 m. In this embodiment, a micrometer stage having a piezo adjuster 504 and a piezo driver 506

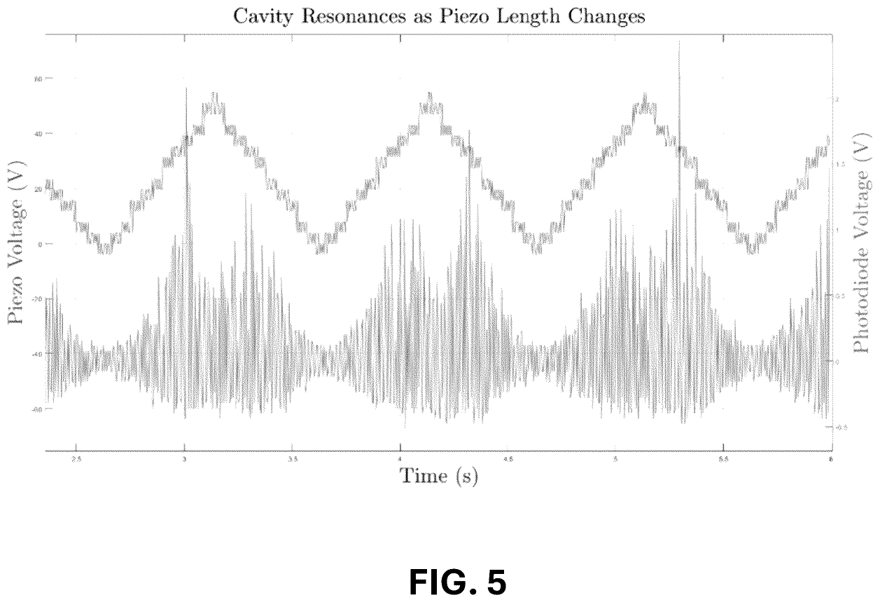

Referring to FIG. 5, cavity output intensity plot is show that was recorded on a DC Biased photodiode (red), Piezo driving voltage (blue) Changes in voltage translate to Piezo displacement of 5 μm in ideal case with no load.

Advantageously, the communication embodiments disclosed herein are simple amplitude modulation which allows for fast and easy development with large amounts of room to iterate and improve the channel capacity. Scattering Compensation

To extend the length of the cavity further and increase efficiency, scattering compensation may be provided. In an embodiment, an active optical device or adaptive optical device (e.g. SLM) may be used to focus a wavefront through a strongly scattering medium. The optimization algorithm employed was the continuous step-wise sequential algorithm (CSA). It should be appreciated that the use of this algorithm may not be the most efficient available for transmission matrix retrieval and compensation, however it was chosen to facilitate implementation. It is recognized that other algorithms may be employed for more efficient and higher quality transmission matrix measurements, such as but not limited to the Gerchberg-Saxton algorithm and its variants.

Other such embodiments may include: a stochastic parallel gradient descent (SPGD) algorithm; a partitioning algorithm for wavefront shaping (e.g., partition the SLM into segments and iteratively update segment phases); a sequential phase stepping/phase-shifting interferometry based optimization algorithm (e.g., three-step or four-step phase stepping per segment); a continuous sequential algorithm (non-stepwise sequential optimization variants); a genetic algorithm optimization of SLM phase patterns; a particle swarm optimization (PSO) of SLM phase patterns; a simulated annealing optimization of SLM phase patterns; a Nelder-Mead simplex optimization of a phase parameterization; a conjugate-gradient optimization of a phase parameterization; and a Kalman-filter-based iterative wavefront estimation and control (e.g., state-space estimation of low-order aberration coefficients driving SLM updates) for example.

It is emphasized that the SLM allows for superimposed phase masks such that one can compensate for diffraction losses, beam tilting, and scattering at the same time while also modulating the signal to provide wireless communication. It is recognized that environments change over time, but there are statistical properties of the transmission matrix for strongly scattering media, namely that its singular values follow a quarter-circle law, which could be leveraged to deal with slow changes to the phase of the transmission matrix.

Embodiments herein provide technical advantages for a single and multi-mode extended cavity laser system capable of remote charging and two-way wireless communication. Embodiments of this system represent a significant advancement in wireless communication and remote charging technology that can extend the usable distance of wireless power transfer beyond current limitations. With the inclusion of an active optical device or adaptive optical device (e.g. SLM) to create a multi-mode resonant beam, the system offers capabilities such as active aberration compensation, beam steering, and data encoding. There are strong technical advantages compared to existing solutions, among which are the innate security of the system, a self-alignment property, the systems efficiency at transmitting at longer distances, and the capability of optical systems for larger channel capacities. Furthermore, embodiments disclosed herein are the first to include cavity based two-way communication, a feature that opens new possibilities for applications in various fields, including satellite communication, UAV operation, and IoT networks.

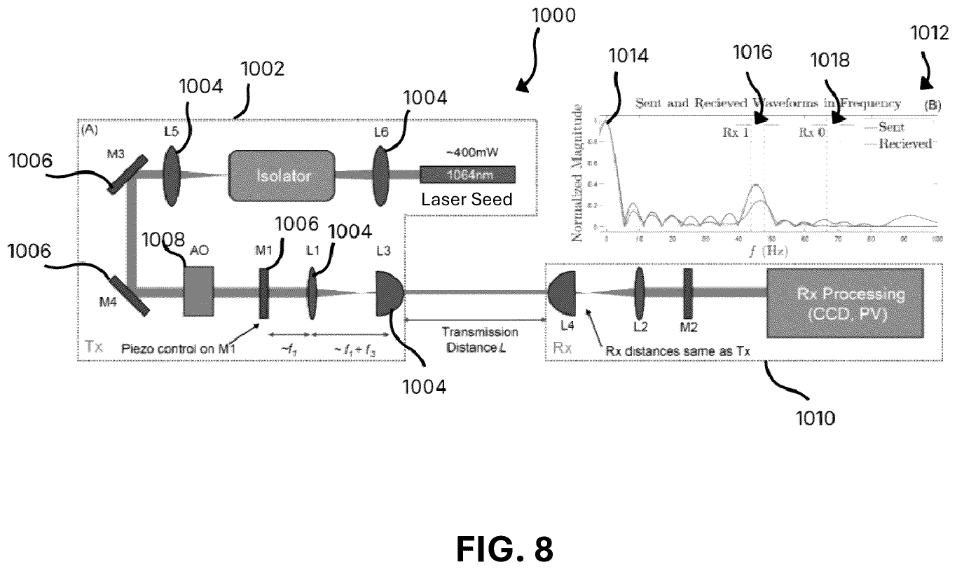

Referring now to FIGS. 8 and 9, additional embodiments are provided.

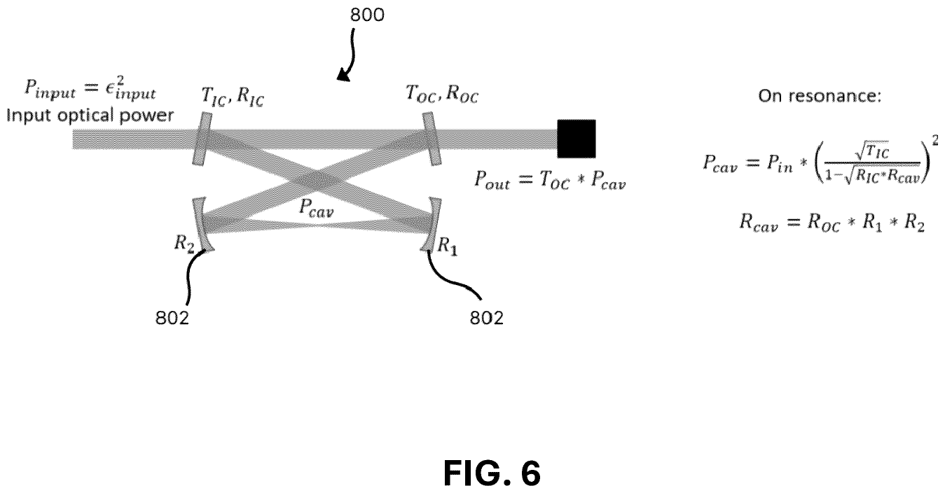

In this embodiment, a method is provided that uses optical enhancement cavities. These cavities can be modeled by only a few properties that are independent of the geometry, i.e. if it is a ring or a linear resonator. For better visibility we will consider a ring resonator 800 as shown in FIG. 6. In this embodiment, parameters for the cavity are: Input power: Pinput; Input coupler reflectivity: RIC; Input coupler transmission: TIC=1−RIC; Output coupler reflectivity: ROC; Output coupler transmission: TOC=1−ROC; and Total cavity reflectivity: RCAV=ROC*R1*R2.

Using these conditions the on-resonance power inside and outside the cavity can be determined by the expression shown in FIG. 6.

The condition for an impedance matched cavity is RCAV=RIC. In this embodiment, it is desirable that the losses inside the cavity are dominated by the output coupler ROC≈RCAV. Other embodiments will work as well at a lower efficiency.

In this embodiment, Pinput=Pout and all the power can be transmitted. Possible losses include: not perfect mode matching, losses on the other mirrors, locking jitter, etc. Overall, this can provide at least 10% of the input power at the output with a very loose lock.

### Lock

Traditionally a cavity needs to be locked in order to have sufficient enhancement, this can be accomplished via different locking algorithms, the most prominent being Hansch-Couillaud and Pound-Drever-Hall.

Other locking algorithms may include: tilt locking (including dither-based slope detection using a cavity reflection or transmission signal); frequency modulation spectroscopy (FMS) locking using applied frequency modulation and demodulation to generate an error signal; side-of-fringe locking using a selected operating point on a resonance flank and feedback based on detected transmitted or reflected intensity; dither-and-demodulate power locking using periodic modulation of cavity length and synchronous detection of intra-cavity power to generate an error signal; digital (software-defined) locking using sampled photodetector signals and a digital controller (e.g., PID or state-space) to maintain a resonance neighborhood; and optical phase-locked loop (OPLL) or injection locking of the optical source to a cavity resonance using heterodyne detection and feedback to a laser actuator (e.g., current or piezo-tuned laser cavity).

In this application, at least in the beginning, the system loosely locks the cavity by oscillating the cavity length around the resonance and providing feedback on the absolute resonance position. It is expected to have at least 20% of a locked cavity, plenty for low power applications. Further development to provide a better lock will improve the throughput. To give a simple example:

$${T}_{IC} : 0.005$$

$${R}_{IC} : 0.995$$

$${R}_{OC} = 0.995$$

$${R}_{cav} = 0.995 * 0.999 * 0.999$$

$$( other mirrors are 99.9 \% )$$

$${P}_{input} = 1 W$$

$${P}_{first pass} = {T}_{IC} * {P}_{in} = 0.005 W$$

$${P}_{cav} = 139 W$$

$${P}_{out} = 0.7 W$$

Even with only 10% of the perfect lock, one would have 70 mW at the output, plenty for low power applications and on par with existing technology.

### Eye Safety

In one or more embodiment, to be conform with eye safety standards a wavelength larger 1200 nm may be used for which up to 10 mW is admissible. This way a 1% input and output coupler can be used. To scale the power even further a multimode cavity can be implemented that has multiple eigenmodes. Each eigenmode (if spaced sufficiently) can have a single path transmission up to the safety limit. Conservative estimations should allow at least 4 beams in the cavity at the same time.

### Working Distance

In the described embodiment of FIG. 6, the working distance is dictated by the two curved mirrors 802 and should extend beyond the sum of the radii of curvature. By going to a linear design, the effective focal length of the ‘end mirrors’ can be tuned to nearly any desired value by using a lens-curved-mirror combination with variable distance between them. This way any effective focal length can be achieved.

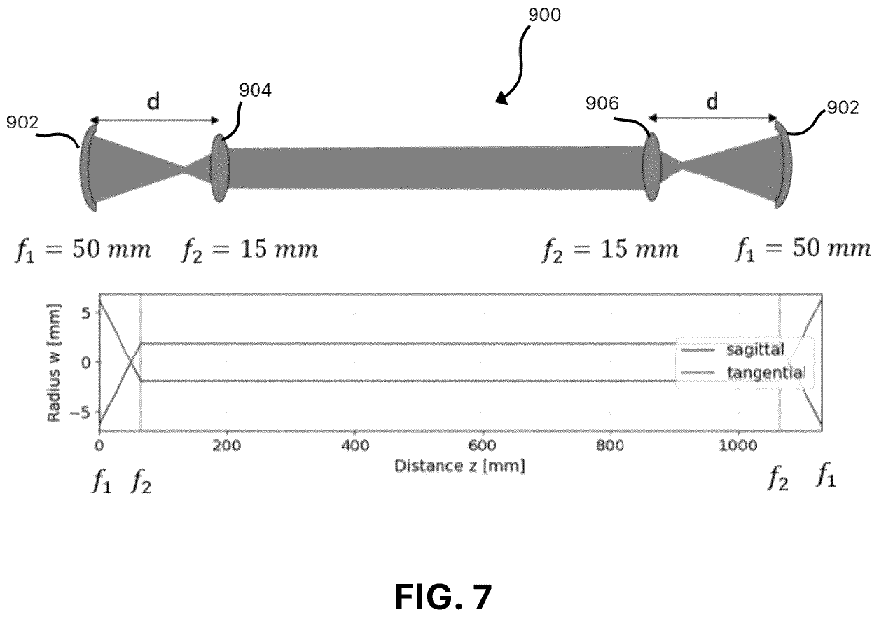

Referring now to FIG. 7 an embodiment of a system 900 is shown using two lenses 904 and 2 curved mirrors 902 to achieve a stable cavity over an extended distance. (in this embodiment 1.3 m). This embodiment can be used for 10s of meters without prohibitively large mode sizes by changing d close to f1+f2. On a product level, a linear cavity design with cat-eye retroreflector that will decrease alignment sensitivity, increase the field of view and allow for long working distances may be used. The optical power after the output coupler can be easily converted to electrical power via, e.g., a photovoltaic cell.

### Advantages

Benefits of a resonant beam system (RBC) include cavity power that rapidly or immediately decays if line of sight (LOS) is lost, power is only spent transmitting in the direction of active devices, and retro-reflector cavity mirrors provide self-alignment of the cavity-even under movement. These properties make resonant beam systems safer and simpler than traditional laser charging systems, which have been used to power UAVs in the air since 2012 and keep them airborne indefinitely.

The use of retro-retroreflectors as the end mirrors of the cavity reduces or eliminates the need for beam pointing when the receiver is in the field-of-view (FOV) of the transmitter, and the fact that that system stops when the cavity is blocked makes it safer in human occupied environments. Additionally, the optical nature of RBC systems allows them to transfer data faster than near-field wireless systems. Current ISO 18000-3 compliant near-field wireless systems have a maximum data rate of 848 kb/s and operate over centimeters. It has been demonstrated that an RBC system is capable of supplying up to 9 W of electrical power to the receiver with an 18-bit/s/Hz spectral efficiency over 20 m distance. Additionally, it has been shown that a 10-bit/s/Hz is an achievable rate at 6-m distance. When these spectral efficiencies are converted using a conservative electrical-optical-modulator bandwidth estimate of 800 MHz, these two papers support data rates well over 8 Gbps at greater distances than near-field wireless systems can offer.

In addition to safety, embodiments herein provide that cavity power exists when line-of-sight is maintained is an innate security feature of a resonant beam system. This feature makes these systems resistant to man-in-the-middle attacks because malicious actors would not be able to intercept the communications. Additionally, “packet sniffing” based on measuring the scattered light is impractical because only an extremely small amount of the light can be recovered and the disclosed communication embodiments modulate the cavity power by about 3%. An RBC system can still be paired with traditional encryption but has innate features that make it more secure. The innate security features of the system can further be improved by developing a communication scheme where light escaping the cavity via scattering loses the information being transmitted because of the randomness associated with scattering.

Embodiments disclosed herein allow for seamless connection and disconnection of client devices from the RBC system without a handshake. A “handshake” as used herein refers to an initial signaling exchange to establish a connection state. In the disclosed embodiments, the receiver can determine if it wants to receive power by changing the state of its active polarizer and the cavity will form or decay automatically. It was mentioned that the self-alignment property reduces or eliminates the need for beam pointing when the receiver is in the transmitter's FOV, but in these embodiments, steering can be still performed by the SLM to further extend the range that the system can operate. The retroreflector based design still reduces the pointing precision used because the SLM may be tilted in the FOV in the neighborhood of the receiver instead of directing a narrow waist to a specific location.

Embodiments provided herein may enable another form of ground to space communication. These embodiments may further be used for IoT applications. First, the disclosed systems allow for devices to charge and communicate wireless similar to near field wireless, but it allows for watts of power to be transmitted over the cavity distance instead of the tens of milliwatts common with NFC devices at comparable distances. Additionally, the multi-mode design allows for receiver position information to be easily extracted by the CCD sensor in the transmitter, allowing the network to provide additional sensing information. The innate security advantages of RBC systems make them ideal for sensitive environments, allowing the benefits of remote sensing to be conferred with reduced or minimal security concerns. The wavelengths used by the system are easily blocked by building walls and can be reflected by windows allowing for networks to be built with minimal information broadcast into the outside world. It is expected that resonant beam based networks can be employed in security sensitive applications to covertly connect devices with reduced network traffic exposure, facilitated by the hardware configuration.

A further embodiment is depicted in FIG. 8. In this example, system 1000 is provided a seeded cat-eye optical cavity 1002 and experimental data 1012 showing one bit in the frequency domain during a BFSK communication scheme performed in a 1.5 m half-symmetric resonator. The cat-eye optical cavity 1002 includes lenses 1004, and mirrors 1006. An adaptive optic 1008 is provided that may be an AOM but will be included after the results shown in (B) are reproduced with the cat-eye cavity. In experimental data 1012, binary data was encoded in a positive triangle wave with two different frequencies where 8 and 12 periods can fit in the same time per bit Tb. The received bit value was determined by integrating the magnitude of the signal 1014 over the first region 1016 and second region 1018 shown and choosing the larger result to map to 0s and 1s. Various other components may be included and called upon for providing for aspects of the teachings herein. For example, additional materials, combinations of materials and/or omission of materials may be used to provide for added embodiments that are within the scope of the teachings herein. Adequacy of any particular element for practice of the teachings herein is to be judged from the perspective of a designer, manufacturer, seller, user, system operator or other similarly interested party, and such limitations are to be perceived according to the standards of the interested party.

In the disclosure hereof any element expressed as a means for performing a specified function is intended to encompass anyway of performing that function including, for example, a) a combination of circuit elements and associated hardware which perform that function or b) software in any form, including, therefore, firmware, microcode or the like as set forth herein, combined with appropriate circuitry for executing that software to perform the function. Applicants thus regard any means which can provide those functionalities as equivalent to those shown herein. No functional language used in claims appended herein is to be construed as invoking 35 U.S.C. § 112(f) interpretations as “means-plus-function” language unless specifically expressed as such by use of the words “means for” or “steps for” within the respective claim.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements. The term “exemplary” is not intended to be construed as a superlative example but merely one of many possible examples.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments described herein.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

1. An optical transfer system comprising:
a transmitter having an optical source in communication with a gain-medium free optical cavity, the transmitter configured to emit a beam of coherent light; and
at least one receiver positioned to receive the beam of coherent light and generate a signal in response.

2. The system of claim 1, wherein the transmitter includes at least one of an active optical device or an adaptive optical device arranged to receive light from the optical source.

3. The system of claim 2, wherein the receiver further includes a photovoltaic cell arranged to receive at least a portion of the beam of coherent light.

4. The system of claim 3, wherein the receiver further includes a beamsplitter positioned to receive the beam of coherent light and transmit the portion of the beam of coherent light to the photovoltaic cell.

5. The system of claim 2, wherein the at least one of an active optical device or an adaptive optical device is a spatial light modulator.

6. The system of claim 5, wherein the transmitter includes a polarizer optically disposed between the spatial light modulator and the gain-medium free optical cavity.

7. The system of claim 6, wherein the transmitter includes at least one photodiode optically disposed to receive light from the polarizer.

8. The system of claim 7, wherein the at least one receiver includes an active waveplate positioned to receive a second portion of the received light beam.

9. The system of claim 2, wherein the at least one receiver is comprised of a first receiver and a second receiver each optically disposed to receive the beam of coherent light.

10. The system of claim 1, wherein the transmitter is disposed on a ground surface and the at least one receiver is disposed on a satellite.

11. The system of claim 1, wherein the transmitter is disposed on a ground surface and the at least one receiver is disposed on an unmanned aerial vehicle.

12. The system of claim 1, wherein the transmitter is disposed on a surface within an interior of a building, and the receiver is coupled to a device within the interior of the building.

13. An optical transfer system comprising:
a transmitter having an optical source in communication with a gain-medium free optical cavity, the transmitter configured to emit a beam of coherent light;
at least one receiver positioned to receive the beam of coherent light and generate a signal in response; and
at least one controller operably coupled to the transmitter and the at least one receiver, the controller having a processor operable to execute computer instructions to perform a method comprising:
causing the transmitter to emit the beam of coherent light towards the receiver;
causing the receiver to receive the beam of coherent light and generate a signal in response to receiving the beam of coherent light; and
storing the signal in at least one of a controller memory or an energy storage device.

14. The system of claim 13, wherein the transmitter includes at least one of an active optical device or an adaptive optical device operably coupled to the controller.

15. The system of claim 14, wherein:
the at least one of an active optical device or an adaptive optical device is a spatial light modulator; and
the method further includes causing the spatial light modulator to modulate the beam of coherent light.

16. The system of claim 15, wherein:
the transmitter further includes a polarizer optically disposed between the spatial light modulator and the gain-medium free optical cavity, and at least one photodiode optically disposed to receive light from the polarizer; and
the method further includes causing the polarizer to polarize light from the optical source and causing the photodiode to transmit a communications signal.

17. The system of claim 16, wherein:
the receiver includes an active waveplate arranged to receive at least a portion of the beam of coherent light; and
the method further includes causing a rotation of a polarization state of the at least a portion of the beam of coherent light with the active waveplate.

18. The system of claim 13, wherein the at least one controller includes a first controller operably coupled to the transmitter and a second controller operably coupled to the receiver.

19. A wireless electrical power and communication transfer system comprising:
a transmitter comprising:
an optical light source;
at least one of an active optical device or an adaptive optical device configured to emit a light beam received from the optical light source;
at least one lens configured to collimate the light beam;
at least one receiver positioned to receive the light beam, the at least one receiver comprising:
a beamsplitter configured to reflect at least a first portion of the received light beam and allow a second portion of the received light beam to pass through;
a photovoltaic cell positioned to receive the first portion; and
a mirror positioned to receive the second portion.

20. The system of claim 19, wherein at least one of an active optical device or an adaptive optical device is a spatial light modulator.
